(19) United States
(12) Patent Application Publication
(10) Pub. No.: US 2009/0249972 A1
(43) Pub. Date: Oct. 8, 2009

(54) METHOD FOR MAKING A LITHOGRAPHIC PRINTING PLATE

(75) Inventor: Eric Verschueren, Merksplas (BE)

Correspondence Address: AGFA;c/o KEATING & BENNETT, LLP, 1800 Alexander Bell Drive, SUITE 200, Reston, VA, 20191, US

(73) Assignee: AGFA GRAPHICS NV, Mortsel (BE)

(21) Appl. No.: 12/088,015

(22) PCT Filed: Sep. 21, 2006
(86) PCT No.: PCT/EP06/66584

§ 371 Date: Mar. 25, 2008

Related U.S. Application Data
(60) Provisional application No. 60/726,963, filed on Oct. 14, 2005.

(30) Foreign Application Priority Data
Sep. 27, 2005 (EP) 05108920.9

(51) Int. Cl. B41F 1/18; G03F 7/20

(52) U.S. Cl. 101/450.1; 430/302; 101/463.1

(57) ABSTRACT

A method for making a lithographic printing plate includes the steps of
providing a lithographic printing plate precursor including a support having a hydrophilic surface or which is provided with a hydrophilic layer, and a coating provided on the hydrophilic surface or the hydrophilic layer, wherein the coating includes an image recording layer including hydrophobic thermoplastic polymer particles and wherein the image recording layer or an optional other layer of the coating further includes an infrared light absorbing agent;
image-wise exposing the precursor to infrared light having an energy density of 190 mJ/cm² or less;
developing the exposed precursor by removing unexposed areas in a processing liquid;
baking the plate thus obtained by keeping the plate at a temperature above the glass transition temperature of the thermoplastic particles during a period between 5 seconds and 2 minutes.

### CROSS-REFERENCE TO RELATED APPLICATIONS

This application is a 371 of PCT/EP2006/066584, filed Sep. 21, 2006. This application claims the benefit of U.S. Provisional Application No. 60/726,963, filed Oct. 14, 2005, which is incorporated by reference herein in its entirety. In addition, this application claims the benefit of European Application No. 05108920.9, filed Sep. 27, 2005, which is also incorporated by reference herein in its entirety.

### BACKGROUND OF THE INVENTION

1. Field of the Invention

The present invention relates to a method for making a wet lithographic printing plate by exposing a heat-sensitive, negative working lithographic printing plate precursor to infrared light, developing the exposed precursor, and then subjecting the plate to a mild baking step.

2. Description of the Related Art

Lithographic printing presses use a so-called printing master such as a printing plate which is mounted on a cylinder of the printing press. The master carries a lithographic image on its surface and a print is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e., ink-accepting, water-repelling) areas as well as hydrophilic (or oleophobic, i.e., water-accepting, ink-repelling) areas. In so-called driographic printing, the lithographic image consists of ink-accepting and ink-abhesive (ink-repelling) areas and during driographic printing, only ink is supplied to the master.

Printing masters are generally obtained by the image-wise exposure and processing of an imaging material called a plate precursor. In addition to the well-known photosensitive, so-called pre-sensitized plates, which are suitable for UV contact exposure through a film mask, heat-sensitive printing plate precursors have also become very popular in the late 1990s. Such thermal materials offer the advantage of daylight stability and are especially used in the so-called computer-to-plate method wherein the plate precursor is directly exposed, i.e., without the use of a film mask. The material is exposed to heat or to infrared light and the generated heat triggers a (physico-)chemical process, such as ablation, polymerization, insolubilization by crosslinking of a polymer, heat-induced solubilization, or by particle coagulation of a thermoplastic polymer latex.

Although some of these thermal processes enable plate making without wet processing, the most popular thermal plates form an image by a heat-induced solubility difference in an alkaline developer between exposed and non-exposed areas of the coating. The coating typically includes an oleophilic binder, e.g., a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support. Negative working embodiments of such thermal materials often require a pre-heat step between exposure and development as described in, e.g., EP-A 625 728.

Negative working plate precursors which do not require a pre-heat step may contain an image-recording layer that works by heat-induced particle coalescence of a thermoplastic polymer latex, as described in, e.g., EP-A 770 494, EP-A 770 495, EP-A 770 496, and EP-A 770 497. These patents disclose a method for making a lithographic printing plate including the steps of (1) image-wise exposing a plate precursor having a heat-sensitive image-recording layer to infrared light, wherein the image-recording layer includes hydrophobic thermoplastic polymer particles, sometimes also referred to as latex particles, which are dispersed in a hydrophilic binder, and (2) developing the image-wise exposed element by applying water or by mounting the plate on the plate cylinder of a press and then supplying fountain solution and/or ink. During the development step, the unexposed areas of the image-recording layer are removed from the support, whereas the latex particles in the exposed areas have coalesced to form a hydrophobic phase which is not removed in the development step. In EP-A 1 342 568, a similar plate precursor is developed with a gum solution and in EP-A 1 614 538, EP-A 1 614 539, and EP-A 1 614 540, development is achieved by means of an alkaline solution.

It is known in the art that lithographic plates, obtained after exposure, development, and optional gumming, can be heat-treated in a so-called post-baking step in order to increase the run length of the plate on the press. A typical post-baking is carried out by heating the plate in an oven at a high temperature, e.g., of about 250° C.

EP-A 1 506 854 describes a method for post-baking various plates, including plates that work by heat-induced latex coalescence, in a short time of 1 minute or less by means of an infrared radiation source.

A problem associated with plate precursors that work according to the mechanism of heat-induced latex coalescence is that it is difficult to obtain both a high sensitivity enabling exposure at a low energy density, and a good clean-out of the unexposed areas during development. The energy density that is required to obtain a sufficient degree of latex coalescence and of adherence of the exposed areas to the support is often higher than 250 mJ/cm². As a result, in platesetters that are equipped with low power exposure devices such as semiconductor infrared laser diodes, such materials require long exposure times.

A higher sensitivity can be obtained, e.g., by providing an image-recording layer that has a better resistance towards the developer in the unexposed state, so that a low energy density suffices to render the image-recording layer completely resistant to the developer. However, such an image-recording layer is difficult to remove during development and results in toning (ink acceptance in the non-image areas). This toning especially occurs when the plate is baked after development. Another way to provide a higher sensitivity can be achieved by using latex particles that are only weakly stabilized so that they coalesce readily, i.e., upon exposure at a low energy density. However, such latex particles tend to also remain on the support in the unexposed state and, again, an insufficient clean-out (removal of the coating during development) is obtained, resulting in toning.

On the other hand, well-stabilized latex particles are easily removed from the support and show no clean-out problems but they require more energy to coalesce and thus a low sensitivity plate is obtained.

### SUMMARY OF THE INVENTION

In order to overcome the problems described above, preferred embodiments of the present invention provide a negative-working lithographic printing plate precursor that works by heat-induced coalescence of thermoplastic polymer particles, which enables both (i) a short exposure time on low power plate setters, and (ii) a good clean-out of the unexposed areas during development resulting in plates which show no toning.

These advantages and benefits are achieved by a method described below, having the specific features that the precursor is exposed at an energy density of 190 mJ/cm² or less, and that the precursor is then subjected to a mild post-baking step, more particularly, to a post-baking step between 5 seconds and 2 minutes.

It was surprisingly discovered that an energy density of 190 mJ/cm² or less, which is typically too low for providing a good adherence of the exposed areas to the support, nevertheless is sufficient to render the exposed areas resistant to the development step. Without being bound to any particular theory, it seems that the mild post-baking step compensates for the underexposure, as explained hereafter. The energy density of 190 mJ/cm² seems to be sufficient to provide enough differentiation between the exposed and unexposed areas to obtain a high-quality lithographic image after development, i.e., a complete clean-out of the unexposed areas without substantially affecting the exposed areas. However, the mechanical and chemical resistance of the (underexposed) lithographic image is insufficient to provide an acceptable run length of the plate during printing. According to the preferred embodiments of the present invention, that problem is solved by the mild post-baking step; i.e., a post baking step between 5 seconds and 2 minutes.

As an additional benefit, the plate-making time is reduced by the combination of both a short exposure time and a short post-baking step. Furthermore, the short post-baking step also reduces the risk of distortion of the support which is often observed after a conventional post-baking step.

Traditionally, baking is carried out by keeping the developed plate in an oven. An advantage of a further preferred embodiment of the present invention enables all steps to be carried out in an integrated plate-making apparatus. The integrated plate-making apparatus preferably includes a plate-setter, a processing unit, and a baking unit. According to the present preferred embodiment, the plate precursor which has been exposed in the plate-setter is mechanically conveyed to the processing unit which is coupled to the plate-setter. After developing the exposed plate in the processing unit, the developed plate is then mechanically conveyed from the processing unit to a baking unit. The short baking step according to the various preferred embodiments of the present invention allows for the use of a small baking unit so that the developed plate is directly conveyed from the processing unit into the baking unit. The plate then travels through the baking unit and leaves the unit within a time period of two minutes or less.

In a preferred embodiment of the present invention, the baking unit includes a cooling zone so that the plate temperature is reduced before the plate leaves the baking unit. The baking unit is preferably equipped with an exhaust to remove volatile compounds that are released by the plate material. The exhaust preferably includes an easily exchangeable filter.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 shows a schematic diagram of a gumming unit.

FIG. 2 shows a schematic diagram of an integrated plate-making apparatus.

FIGS. 3A and 3B show the rendering of a 10% screen of 200 lpi (lines per inch) or about 80 lines/cm, on a printed copy produced with comparative printing plates 1 and 2 and inventive printing plate 3 (see Examples: Print Results).

### DETAILED DESCRIPTION OF THE PREFERRED EMBODIMENTS

The support of the lithographic printing plate precursor used in a preferred method of the present invention has a hydrophilic surface or is provided with a hydrophilic layer. The support may be a sheet-like material such as a plate or it may be a cylindrical element such as a sleeve which can be slid around a print cylinder of a printing press. Preferably, the support is a metal support such as aluminum or stainless steel. The support can also be a laminate including an aluminum foil and a plastic layer, e.g., polyester film.

A particularly preferred lithographic support is an electrochemically grained and anodized aluminum support. The aluminum is preferably grained by electrochemical graining, and anodized by anodizing techniques employing phosphoric acid or a sulphuric acid/phosphoric acid mixture. Methods of both graining and anodization of aluminum are very well known in the art. By graining (or roughening) the aluminum support, both the adhesion of the printing image and the wetting characteristics of the non-image areas are improved. By varying the type and/or concentration of the electrolyte and the applied voltage in the graining step, different types of grains can be obtained. By anodizing the aluminum support, its abrasion resistance and hydrophilic nature are improved. The microstructure as well as the thickness of the Al₂O₃ layer are determined by the anodizing step, the anodic weight (g/m² Al₂O₃ formed on the aluminum surface) may vary between 1 g/m² and 8 g/m².

The grained and anodized aluminum support may be post-treated to improve the hydrophilic properties of its surface. For example, the aluminum oxide surface may be silicated by treating its surface with a sodium silicate solution at elevated temperature, e.g., 95° C. Alternatively, a phosphate treatment may be applied which involves treating the aluminum oxide surface with a phosphate solution that may further contain an inorganic fluoride. Further, the aluminum oxide surface may be rinsed with an organic acid and/or salt thereof, e.g., carboxylic acids, hydrocarboxylic acids, sulphonic acids, or phosphonic acids, or their salts, e.g., succinates, phosphates, phosphonates, sulphates, and sulphonates. A citric acid or citrate solution is preferred. This treatment may be carried out at room temperature or may be carried out at a slightly elevated temperature of about 30° C. to 50° C. A further interesting treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde. It is further evident that one or more of these post treatments may be carried out alone or in combination. More detailed descriptions of these treatments are given in GB 1084070, DE 4423140, DE 4417907, EP 659909, EP 537633, DE 4001466, EP-A 292801, EP-A 291760, and U.S. Pat. No. 4,458,005.

According to another preferred embodiment, the support can also be a flexible support, which is provided with a hydrophilic layer, hereinafter called a ‘base layer’. The flexible support is, e.g., paper, plastic film, thin aluminum or a laminate thereof. Preferred examples of plastic film are polyethylene terephthalate film, polyethylene naphthalate film, cellulose acetate film, polystyrene film, polycarbonate film, etc. The plastic film support may be opaque or transparent.

The base layer is preferably a cross-linked hydrophilic layer obtained from a hydrophilic binder cross-linked with a hardening agent such as formaldehyde, glyoxal, polyisocyanate, or a hydrolyzed tetra-alkylorthosilicate. The latter is particularly preferred. The thickness of the hydrophilic base layer may vary in the range of 0.2 μm to 25 μm and is preferably 1 μm to 10 μm. The hydrophilic binder for use in the base layer is, e.g., a hydrophilic (co)polymer such as homopolymers and copolymers of vinyl alcohol, acrylamide, methylol acrylamide, methylol methacrylamide, acrylate acid, methacrylate acid, hydroxyethyl acrylate, hydroxyethyl methacrylate, or maleic anhydride/vinylmethylether copolymers. The hydrophilicity of the (co)polymer or (co)polymer mixture used is preferably the same as or higher than the hydrophilicity of polyvinyl acetate hydrolyzed to at least an extent of 60% by weight, preferably 80% by weight. The amount of hardening agent, in particular tetra-alkyl orthosilicate, is preferably at least 0.2 parts per part by weight of hydrophilic binder, more preferably between 0.5 and 5 parts by weight, most preferably between 1 part and 3 parts by weight.

According to another preferred embodiment, the base layer may also include Al₂O₃ and an optional binder. Deposition methods for the Al₂O₃ onto the flexible support may be (i) physical vapor deposition including reactive sputtering, RF-sputtering, pulsed laser PVD and evaporation of aluminum, (ii) chemical vapor deposition under both vacuum and non-vacuum conditions, (iii) chemical solution deposition including spray coating, dipcoating, spincoating, chemical bath deposition, selective ion layer adsorption and reaction, liquid phase deposition, and electroless deposition. The Al₂O₃ powder can be prepared using different techniques including flame pyrolisis, ball milling, precipitation, hydrothermal synthesis, aerosol synthesis, emulsion synthesis, sol-gel synthesis (solvent based), solution-gel synthesis (water based) and gas phase synthesis. The particle size of the Al₂O₃ powders can vary between 2 nm and 30 μm; more preferably between 100 nm and 2 μm.

The hydrophilic base layer may also contain substances that increase the mechanical strength and the porosity of the layer. For this purpose colloidal silica may be used. The colloidal silica employed may be in the form of any commercially available water dispersion of colloidal silica for example having a particle size up to 40 nm, e.g., 20 nm. In addition, inert particles of a larger size than the colloidal silica may be added, e.g., silica prepared according to Stöber as described in J. Colloid and Interface Sci., Vol. 26, 1968, pages 62 to 69, or alumina particles or particles having an average diameter of at least 100 nm which are particles of titanium dioxide or other heavy metal oxides.

Particular examples of suitable hydrophilic base layers for use in accordance with the preferred embodiments of the present invention are disclosed in EP 601240, GB 1419512, FR 2300354, U.S. Pat. No. 3,971,660, and U.S. Pat. No. 4,284,705.

The coating on the support preferably includes hydrophobic thermoplastic particles. The coating may include one or more layer(s) and the layer including the hydrophobic thermoplastic particles is referred to herein as an ‘image-recording layer’. The weight average molecular weight of the thermoplastic polymer particles may range from 5,000 g/mol to 1,000,000 g/mol. The hydrophobic particles preferably have a number average particle diameter below 200 nm, more preferably between 10 and 100 nm. In a specific preferred embodiment, the average particle size is included between 40 nm and 70 nm, more preferably between 45 nm and 65 nm. The particle size is defined herein as the particle diameter, measured by Photon Correlation Spectrometry, also known as Quasi-Elastic or Dynamic Light-Scattering. This technique produces values of the particle size that match well with the particle size measured with transmission electronic microscopy (TEM) as disclosed by Stanley D. Duke et al. in Calibration of Spherical Particles by Light Scattering, in Technical Note-002B, May 15, 2000 (revised Jan. 3, 2000 from a paper published in Particulate Science and Technology 7, pp. 223-228 (1989)). An optimal ratio between the pore diameter of the hydrophilic surface of the aluminum support (if present) and the average particle size of the hydrophobic thermoplastic particles may enhance the press run length of the plate and may improve the toning behaviour of the prints. The ratio of the average pore diameter of the hydrophilic surface of the aluminum support to the average particle size of the polymer particles preferably ranges from 0.05:1 to 0.8:1, more preferably from 0.10:1 to 0.35:1.

The amount of hydrophobic thermoplastic polymer particles contained in the image-recording layer is preferably between 20 and 90 percent by weight (wt. %), relative to the weight of all the components in the image-recording layer. In a preferred embodiment, the amount of hydrophobic thermoplastic polymer particles present in the image-recording layer is at least 70 wt. % and more preferably at least 75 wt. %. An amount between 75 and 85 wt. % produces excellent results.

Suitable examples of polymers present in the hydrophobic thermoplastic polymer particles are polyethylene, poly(vinyl)chloride, polymethyl(meth)acrylate, polyethyl (meth)acrylate, polyvinylidene chloride, poly(meth)acrylonitrile, polyvinylcarbazole, polystyrene or copolymers thereof. According to a preferred embodiment, the thermoplastic polymer particles include polystyrene or derivatives thereof. Mixtures including polystyrene or derivatives thereof and copolymers of styrene or derivatives thereof are most preferred.

In order to obtain sufficient resistivity towards organic chemicals such as hydrocarbons used in plate cleaners, the hydrophobic thermoplastic polymer particles preferably include nitrogen containing monomeric units or units which correspond to monomers that are characterized by a solubility parameter larger than 20, such as (meth)acrylonitrile or monomeric units including sulfonamide and/or phthalimide pendant groups. Other suitable examples of such units are disclosed in EP 1,219,416. The average amount of the units is at least 5 wt. %, more preferably at least 30 wt. % of the polymer particle.

A preferred embodiment of the hydrophobic thermoplastic polymer is a copolymer including polystyrene and poly(meth)acrylonitrile or derivatives thereof. The latter copolymers may include at least 50% by weight of polystyrene, and more preferably at least 65% by weight of polystyrene. According to a more preferred embodiment, the thermoplastic polymer particles consist essentially of styrene and acrylonitrile units in a weight ratio between 1:1 and 5:1 (styrene:acrylonitrile), e.g., in a 2:1 ratio.

The hydrophobic thermoplastic polymer particles present in the image-recording layer can be applied onto the lithographic base in the form of a dispersion in an aqueous coating liquid and may be prepared by the methods disclosed in U.S. Pat. No. 3,476,937 or EP 1,217,010. Another method especially suitable for preparing an aqueous dispersion of the thermoplastic polymer particles includes dissolving the hydrophobic thermoplastic polymer in an organic water immiscible solvent, dispersing the thus obtained solution in water or in an aqueous medium, and removing the organic solvent by evaporation.

The image-recording layer preferably further includes a hydrophilic binder. Examples of suitable hydrophilic binders are homopolymers and copolymers of vinyl alcohol, acrylamide, methylol acrylamide, methylol methacrylamide, acrylic acid, methacrylic acid, hydroxyethyl acrylate, hydroxyethyl methacrylate, and maleic anhydride/vinylmethylether copolymers.

The coating preferably also contains a compound which absorbs infrared light and converts the absorbed energy into heat. The amount of infrared absorbing agent in the coating is preferably between 0.25% and 25.0% by weight, more preferably between 0.5% and 20.0% by weight. The infrared absorbing compound can be present in the image-recording layer and/or an optional other layer. In the preferred embodiment wherein the infrared absorbing agent is present in the image-recording layer of the coating, its concentration is preferably at least 6% by weight, more preferably at least 8% by weight, relative to the weight of all the components in the image-recording layer. Preferred IR absorbing compounds are dyes such as cyanine, merocyanine, indoaniline, oxonol, pyrilium, and squarilium dyes or pigments such as carbon black. Examples of suitable IR absorbers are described in, e.g., EP-A 823327, EP-A 978376, EP-A 1029667, EP-A 1053868, EP-A 1093934, WO 97/39894, and WO 00/29214. A preferred compound is the following cyanine dye IR-1 or a suitable salt thereof:

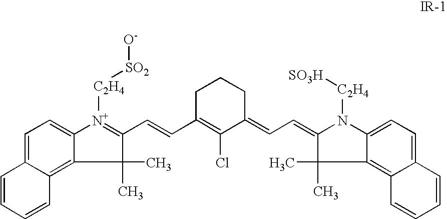

To protect the surface of the coating, in particular from mechanical damage, a protective layer may also optionally be applied. The protective layer generally includes at least one water-soluble polymeric binder, such as polyvinyl alcohol, polyvinylpyrrolidone, partially hydrolyzed polyvinyl acetates, gelatin, carbohydrates, or hydroxyethylcellulose, and can be produced in any known manner such as from an aqueous solution or dispersion which may, if required, contain small amounts of organic solvents, e.g., less than 5% by weight, based on the total weight of the coating solvents for the protective layer. The thickness of the protective layer can suitably be any amount, advantageously up to 5.0 μm, preferably from 0.05 μm to 3.0 μm, particularly preferably from 0.10 μm to 1.0 μm.

Besides the additional layers already discussed above, i.e., an optional light-absorbing layer including one or more compounds that are capable of converting infrared light into heat and/or a protective layer such as, e.g., a covering layer which is removed during processing, the coating may further include other additional layer(s) such as, for example, an adhesion-improving layer between the image-recording layer and the support.

Optionally, the coating may further contain additional ingredients. These ingredients may be present in the image-recording layer or in an optional other layer. For example, additional binders, polymer particles such as matting agents and spacers, surfactants such as perfluoro surfactants, silicon or titanium dioxide particles, development inhibitors, development accelerators, or colorants are well-known components of lithographic coatings. Especially, addition of colorants such as dyes or pigments which provide a visible color to the coating and remain in the exposed areas of the coating after the processing step, are advantageous. Thus, the image-areas which are not removed during the processing step form a visible image on the printing plate and examination of the developed printing plate already at this stage becomes feasible. Typical examples of such contrast dyes are phthalocyanines or the amino-substituted tri- or diarylmethane dyes, e.g., crystal violet, methyl violet, victoria pure blue, flexoblau 630, basonylblau 640, auramine, and malachite green. Also the dyes which are discussed in depth in the detailed description of EP-A 400,706 are suitable contrast dyes. Dyes which, combined with specific additives, only slightly color the coating but which become intensively colored after exposure, are also of interest.

The printing plate precursor of the various preferred embodiments of the present invention is preferably image-wise exposed by infrared light, preferably near infrared light. The infrared light is preferably converted into heat by an IR light absorbing compound as discussed above. The heat-sensitive lithographic printing plate precursor of the various preferred embodiments of the present invention is preferably not sensitive to visible light. Most preferably, the coating is not sensitive to ambient daylight, i.e., visible (400-750 nm) and near UV light (300-400 nm) at an intensity and exposure time corresponding to normal working conditions so that the material can be handled without the need for a safe light environment.

The printing plate precursors of the various preferred embodiments of the present invention can be exposed to infrared light by, e.g., LEDs or an infrared laser. Preferably, the light used for the exposure is a laser emitting near infrared light having a wavelength in the range from about 700 nm to about 1500 nm, e.g., a semiconductor laser diode, a Nd:YAG or a Nd:YLF laser. In accordance with the various preferred embodiments of the present invention, the energy density of the light used in the exposure step is 190 mJ/cm² or less, more preferably 180 mJ/cm² or less. Satisfactory results can also be obtained at an energy density of 160 mJ/cm² or less or even at 150 mJ/cm² or less.

Due to the heat generated during the exposure step, the hydrophobic thermoplastic polymer particles fuse or coagulate so as to form a hydrophobic phase which corresponds to the printing areas of the printing plate. Coagulation may result from heat-induced coalescence, softening or melting of the thermoplastic polymer particles. There is no specific upper limit to the coagulation temperature of the thermoplastic hydrophobic polymer particles, however the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

After exposure, the precursor is developed by a suitable processing liquid. In the development step, the non-exposed areas of the image-recording layer are removed without essentially removing the exposed areas, i.e., without affecting the exposed areas to an extent that renders the ink-acceptance of the exposed areas unacceptable. The processing liquid can be applied to the plate, e.g., by rubbing in with an impregnated pad, by dipping, (spin-)coating, spraying, pouring-on, either by hand or in an automatic processing apparatus. The treatment with a processing liquid may be combined with mechanical rubbing, e.g., by a rotating brush. The developed plate precursor can, if required, be post-treated with rinse water, a suitable correcting agent, or preservative as known in the art. During the development step, any water-soluble protective layer present is preferably also removed.

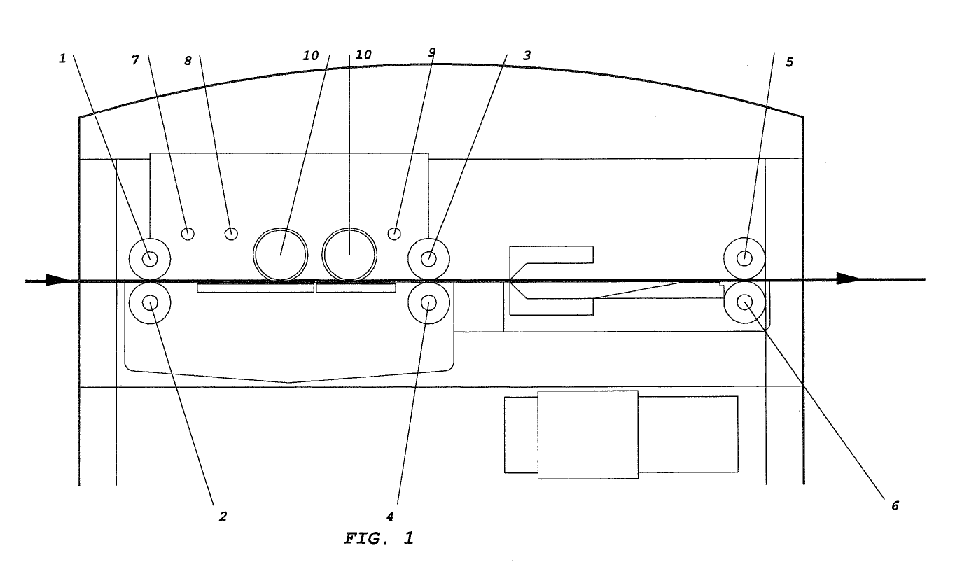

Suitable processing liquids are plain water or aqueous solutions, e.g., a gumming solution or an alkaline solution. Gumming solutions which are suitable as a processing liquid preferably have a pH between 4 and 10 and have been described in EP-A 1 342 568. In a preferred embodiment, the processing step of the exposed plate is carried out using a gumming unit as shown in FIG. 1. The gumming unit includes (i) rollers 1 to 6 for transporting the plate through the device, (ii) spray tubes 7, 8, and 9 for applying the gum liquid, and (iii) scrub rollers 10.

A preferred embodiment using an alkaline solution is now described in more detail. A preferred aqueous alkaline solution has a pH of at least 10, more preferably at least 11, most preferably at least 12. In a preferred embodiment, the pH is between 10 and 14. Preferred aqueous alkaline solutions are buffer solutions such as for example silicate-based developers or developer solutions including phosphate buffers. Silicate-based developers which have a ratio of silicon dioxide to alkali metal oxide of at least 1 are advantageous because they ensure that the alumina layer (if present) of the substrate is not damaged. Preferred alkali metal oxides include Na₂O and K₂O, and mixtures thereof. A particularly preferred silicate-based developer solution is a developer solution including sodium or potassium metasilicate, i.e., a silicate where the ratio of silicon dioxide to alkali metal oxide is 1.

In addition to alkali metal silicates, the developer may optionally contain further components, such as buffer substances, complexing agents, antifoams, organic solvents in small amounts, corrosion inhibitors, dyes, surfactants and/or hydrotropic agents as known in the art.

The development is preferably carried out at temperatures of from 20° C. to 40° C. in automated processing units as customary in the art. For regeneration, alkali metal silicate solutions having alkali metal contents of from 0.6 mol/l to 2.0 mol/l can suitably be used. These solutions may have the same silica/alkali metal oxide ratio as the developer (generally, however, it is lower) and likewise optionally contain further additives. The required amounts of regenerated material must be tailored to the developing apparatuses used, daily plate throughputs, image areas, etc., and are in general from 1 ml to 50 ml per square meter of plate precursor. The addition of replenisher can be regulated, for example, by measuring the conductivity of the developer as described in EP-A 556,690.

In accordance with a preferred embodiment of the present invention, the developed plate is subjected to a mild post-baking step during a baking period of two minutes or less, i.e., between 5 seconds and 2 minutes. Preferably, the baking period is less than one minute, more preferably less than 30 seconds. The developed plate can be dried before baking or is dried during the baking process itself. During the baking step, the plate is heated up to a baking temperature which is higher than the glass transition temperature of the thermoplastic particles. A preferred baking temperature is above 50° C., more preferably above 100° C. ‘Baking temperature’ as used herein refers to the temperature of the plate during the baking process. In a preferred embodiment, the baking temperature does not exceed 300° C. during the baking period. More preferably, the baking temperature does not exceed 250° C., not even 220° C. Baking can be done in conventional hot air ovens or by irradiation with lamps emitting infrared light as disclosed in EP-A 1 506 854.

The baking temperature can be measured by one or more temperature probes, e.g., thermocouples, preferably fixed to the backside of the support. Since the coating is very thin (typically less than 1 μm) relative to the support, the temperature of the coating is essentially equal to the temperature of the support. Especially when using large plates, it may be observed that the temperature profile (temperature versus time) during the baking process at one spot on the plate, e.g., near the edge, is different from the temperature profile at another spot, e.g., near the center of the plate. In such a case, it is preferred that the temperature at any spot on the plate does not exceed a temperature of 300° C., more preferably a temperature of 250° C., and most preferably a temperature of 200° C.

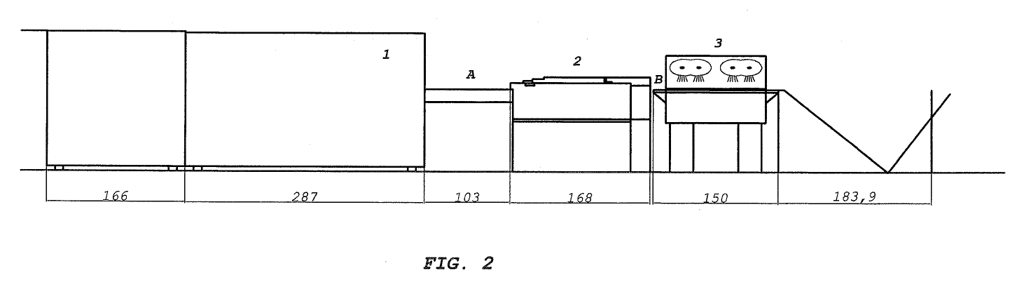

In a preferred embodiment, the exposure step, the processing step, and the baking step are carried out in an integrated plate-making apparatus (FIG. 2). The integrated plate-making apparatus includes a plate-setter (1), a processing unit (2), and a small baking unit (3). The plate precursor which has been exposed in the plate-setter is mechanically conveyed via a transferring device A to the processing unit which is further coupled via a transferring device B to the baking unit. After developing the exposed plate in the processing unit, the developed plate is then mechanically conveyed via transferring device B to the baking unit. The short baking step according to the various preferred embodiments of the present invention allows the use of a small baking unit (preferred dimensions of the different units of the plate-making apparatus are indicated in FIG. 2 in cm). The plate then travels through the baking unit and leaves the unit preferably within a time period of two minutes or less. The baking unit may further include a cooling zone so that the plate temperature is reduced before the plate leaves the baking unit. Furthermore, the baking unit is preferably equipped with an exhaust which removes volatile compounds that may be released from the plate material. The exhaust preferably includes an easily exchangeable filter.

The printing plate thus obtained can be used for conventional, so-called wet offset printing, in which ink and an aqueous dampening liquid are supplied to the plate. Another suitable printing method uses a so-called single-fluid ink without a dampening liquid. Suitable single-fluid inks have been described in U.S. Pat. No. 4,045,232; U.S. Pat. No. 4,981,517; and U.S. Pat. No. 6,140,392. In another preferred embodiment, the single-fluid ink includes an ink phase, also called the hydrophobic or oleophilic phase, and a polyol phase as described in WO 00/32705.

### EXAMPLES

### 1. Preparation of the Lithographic Support

A 0.30 mm thick aluminum foil was degreased by immersing the foil in an aqueous solution containing 40 g/l of sodium hydroxide at 60° C. for 8 seconds and rinsed with demineralized water for 2 seconds. The foil was then electrochemically grained for 15 seconds using an alternating current in an aqueous solution containing 12 g/l of hydrochloric acid and 38 g/l of aluminum sulfate (18-hydrate) at a temperature of 33° C. and a current density of 130 A/dm². After rinsing with demineralized water for 2 seconds, the aluminum foil was then desmutted by etching with an aqueous solution containing 155 g/l of sulfuric acid at 70° C. for 4 seconds and rinsed with demineralized water at 25° C. for 2 seconds. The foil was subsequently subjected to anodic oxidation during 13 seconds in an aqueous solution containing 155 g/l of sulfuric acid at a temperature of 45° C. and a current density of 22 A/dm², then washed with demineralized water for 2 seconds and post-treated for 10 seconds with a solution containing 4 g/l of polyvinylphosphonic acid at 40° C., rinsed with demineralized water at 20° C. during 2 seconds and dried. The support thus obtained has a surface roughness Ra of 0.21 μm and an anodic weight of 4 g/m² of Al₂O₃.

### 2. Preparation of the Printing Plate Precursor

A printing plate precursor was produced by applying a coating onto the above described lithographic support. The aqueous coating solution had a pH of 3.55 and included the compounds listed in Table 1. After drying, the coating weight was 0.678 g/m².

TABLE 1
Composition of the Dry Coating

| INGREDIENTS | wt. % |
|---|---|
| Styrene/acrylonitrile copolymer (1) | 82.18 |
| Cu-phtalocyanine pigment (2) | 2.97 |
| Triethylammonium salt of IR-1 (3) | 7.92 |
| Polyacrylic acid binder (4) | 5.94 |
| Zonyl FSO 100 (5) | 1.00 |

(1) weight ratio 60/40, stabilized with an anionic wetting agent; particle size of 50 nm, measured with a Brookhaven BI-90 analyzer, commercially available from Brookhaven Instrument Company, Holtsville, NY, USA.
(2) Cab O Jet 250 from Cabot Corporation, added as 5% aqueous dispersion.
(3) infrared dye defined above.
(4) Aquatreat AR-7H from National Starch & Chemical Company, Mw = 500 000 g/mol.
(5) Surfactant from Dupont.

### 3. Preparation of the Printing Plates

The obtained printing plate precursors were exposed with a CREO Trendsetter TE318 (40W) (plate-setter available from Creo, Burnaby, Canada), operating at an energy density of, respectively, 140 mJ/cm² (comparative printing plate 1 and inventive printing plate 3) and 200 mJ/cm² (comparative printing plate 2) and at 150 rpm (Table 2).

After imaging, the printing plate precursors 1-3 were processed in an Agfa VA88 processor, operating at a speed of 1 m/min and at 22° C., and using Agfa TD1000 as a developer solution and RC520 as a gum solution; both trademarks of Agfa.

Printing plates 1 and 2 were mounted as such on the printing press while inventive printing plate 3 was baked prior to mounting it on the press (Table 2). The baking step of inventive printing plate 2 was carried out by heating the plate with an infrared radiation source at a temperature of 200° C. and a dwell-time of the baking step for 20 seconds.

TABLE 2
Applied Energy Density and Baking Conditions

| | Applied energy | Baking | |
|---|---|---|---|
| | density | temperature | Baking |
| Printing plate | mJ/cm² | ° C. | periods |
| Comparative | 140 | — | — |
| printing plate 1 (1) | | | |
| Comparative | 200 | — | — |
| printing plate 2 (1) | | | |
| Inventive | 140 | 200 | 20 |
| Printing plate 3 | | | |

(1): the comparative printing plates 1 and 2 are not baked.

### 4. Print Results

The obtained printing plates were mounted on a Drent printing press (available from Drent Goebel), and a print job was started using Arets UV cyan EXC ink (trademark of Arets Graphics) and 2.5% FS405 in 10% isopropanol as a fountain liquid.

The lithographic properties of the plates were determined by visual examination of the prints after respectively 10,000 sheets and 55,000 sheets. The quality of the coating was determined by inspection of the rendering of a 10% screen of 200 lpi on print.

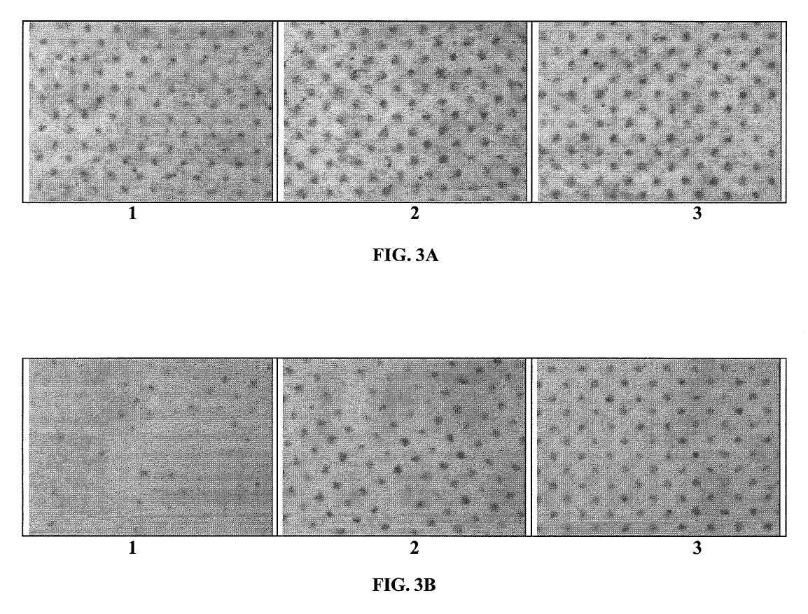

The results are presented in Table 3 and FIGS. 3A and 3B: at an exposure density of 140 mJ/cm² and 200 mJ/cm² the rendering of a 10% screen of 200 lpi on print measured after 10,000 sheets is similar for the three plates (FIG. 3A, 1=printing plate 1, 2=printing plate 2, and 3=printing plate 3). Furthermore, the rendering of a 10% screen of 200 lpi on print measured after 55,000 sheets of inventive printing plate 3 (3, FIG. 3B), which has been underexposed and baked, is similar to comparative printing plate 2 (2, FIG. 3B) which has been exposed at 200 mJ/cm² while the rendering of the 10% screen of 200 lpi on print after 55,000 sheets of comparative printing plate 1 (1, FIG. 3B) which has been exposed at 140 mJ/cm² but was not baked, is damaged and almost not present any more on print. Thus, the mechanical and chemical resistance of the (underexposed) lithographic image exposed at an energy density of 140 mJ/cm² is unsufficient to retain an acceptable coating quality of the plate during printing, while the mild post-baking step seems to compensate for the underexposure (3, FIG. 3).

TABLE 3
Rendering of a 10% Screen of 200 lpi on Print

Rendering of a 10% screen of 200
lpi on print(1)

| | After 10,000 | After 55,000 |
|---|---|---|
| | sheets | sheets |
| Comparative | + | − |
| printing plate 1 | | |
| Comparative | + | + |
| printing plate 2 | | |
| Inventive | + | + |
| Printing plate 3 | | |

(1) +: indicates that the 10% screen of 200 lpi on print is unaffected. −: indicates that the 10% screen of 200 lpi on print is damaged.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-16. (canceled)

17. A method for making a lithographic printing plate comprising the steps of:
providing a lithographic printing plate precursor including:
a support having a hydrophilic surface or which is provided with a hydrophilic layer; and
a coating provided on the hydrophilic surface or the hydrophilic layer; wherein
the coating includes an image recording layer including hydrophobic thermoplastic polymer particles, and the image recording layer or an optional other layer of the coating further includes an infrared light absorbing agent;
image-wise exposing the precursor to infrared light having an energy density of 190 mJ/cm² or less;
developing the exposed precursor by removing unexposed areas in a processing liquid;
baking the plate thus obtained by keeping the plate at a temperature above a glass transition temperature of the thermoplastic particles for a period between 5 seconds and 2 minutes.

18. The method according to claim 17, wherein the energy density is 180 mJ/cm² or less.

19. The method according to claim 17, wherein the energy density is 160 mJ/cm² or less.

20. The method according to claim 17, wherein the energy density is 150 mJ/cm² or less.

21. The method according to claim 17, wherein the baking period is less than 1 minute.

22. The method according to claim 18, wherein the baking period is less than 30 seconds.

23. The method according to claim 19, wherein the temperature of the plate does not exceed 300° C. during the baking period.

24. The method according to claim 22, wherein the temperature of the plate does not exceed 250° C. during the baking period.

25. The method according to claim 20, wherein the temperature of the plate does not exceed 200° C. during the baking period.

26. The method according to claim 17, wherein the hydrophobic thermoplastic polymer particles have an average particle size between 40 nm and 70 nm.

27. The method according to claim 17, wherein the image-recording layer further includes a binder, and the amount of the hydrophobic thermoplastic polymer particles is at least 70% by weight relative to the image-recording layer.

28. The method according to claim 17, wherein the processing liquid is water or an aqueous solution.

29. The method according to claim 17, wherein the processing liquid is a gum solution having a pH between 4 and 10.

30. The method according to claim 17, wherein the processing liquid is an alkaline solution having a pH between 10 and 14.

31. The method according to claim 17, further comprising:
making the lithographic printing plate in a plate-making apparatus, the plate-making apparatus including:
a plate-setter;
a processing unit; and
a bake unit; wherein
the plate-setter is mechanically coupled to the processing unit which is further coupled to the bake unit.

32. A method of lithographic printing comprising the steps of:
making a lithographic printing plate by the method according to claim 17;
mounting the plate on a plate cylinder of a lithographic printing press;
supplying ink and fountain solution to the plate; and
transferring the ink to paper.
